(19) United States
(12) Patent Application Publication
(10) Pub. No.: US 2014/0070186 A1
(43) Pub. Date: Mar. 13, 2014

(54) ORGANIC LIGHT EMITTING DIODE DISPLAY AND MANUFACTURING METHOD THEREOF

(71) Applicant: Seon-Hee KIM, Yongin-City (KR)

(72) Inventor: Seon-Hee KIM, Yongin-City (KR)

(21) Appl. No.: 13/920,398

(22) Filed: Jun. 18, 2013

(30) Foreign Application Priority Data
Sep. 10, 2012 (KR) 10-2012-0099924

(51) Int. Cl. H01L 51/52; H01L 51/56

(52) U.S. Cl. CPC H01L 51/5203; H01L 51/56
USPC 257/40; 438/28; 257/88

(57) ABSTRACT

An organic light emitting diode display includes a substrate, a first electrode on the substrate, an emission layer on the first electrode, a second electrode on the emission layer, and an encapsulation layer on the second electrode. The encapsulation layer has a multilayered structure and a photochromic material is within at least one layer of the multilayered structure.

### CROSS-REFERENCE TO RELATED APPLICATION

This application claims priority under 35 U.S.C. §119 to Korean Patent Application No. 10-2012-0099924, filed on Sep. 10, 2012, in the Korean Intellectual Property Office, the disclosure of which is incorporated herein in its entirety by reference.

### BACKGROUND

An organic light emitting diode is being spotlighted as the next-generation display due to merits such as low-voltage driving, light and thin body type, a light viewing angle, and a fast response speed. Recently, research on a flexible display device using the organic light emitting diode is being conducted.

### SUMMARY

Embodiments may be realized by providing an organic light emitting diode display that includes a substrate, a first electrode formed on the substrate, an emission layer formed on the first electrode, a second electrode formed on the emission layer, and an encapsulation layer formed on the second electrode, in which the encapsulation layer is formed in a multilayered structure, and a photochromic material is contained in at least one layer thereof.

The photochromic material may contain an ultraviolet sensitive material. The photochromic material may include at least one selected from spiroxazine-based, spiropyran-based, azobenzo-based, naphthopyran-based, and chromene-based organic materials, AgCl, WO₃, TiO₂, and ZnS.

The encapsulation layer may include at least one organic layer and at least one inorganic layer. The at least one organic layer may contain a photochromic material.

The content of the photochromic material may be 1% to 20% in the organic layer containing the photochromic material.

Embodiments may also be realized by providing a manufacturing method of an organic light emitting diode display, which method includes forming a first electrode on a substrate, forming an emission layer on the first electrode, forming a second electrode on the emission layer, and forming an encapsulation layer on the second electrode, in which the forming of the encapsulation layer includes forming a layer containing a photochromic material.

The photochromic material may contain an ultraviolet sensitive material. The photochromic material may include at least one selected from spiroxazine-based, spiropyran-based, azobenzo-based, naphthopyran-based, and chromene-based organic materials, AgCl, WO₃, TiO₂, and ZnS.

The forming of the encapsulation layer may include forming an organic layer and forming an inorganic layer. The forming of the organic layer and the forming of the inorganic layer may be alternately performed. The forming of the organic layer and the forming of the inorganic layer may be performed by using any one method of printing, depositing, and sputtering. The forming of the organic layer may include forming an organic layer containing a photochromic material.

The forming of the organic layer containing the photochromic material may be performed by co-depositing method of a material for forming the organic layer and the photochromic material. The forming of the organic layer containing the photochromic material may include dispersing the photochromic material into the material for forming the organic layer and coating the material for forming the organic layer in which the photochromic material is dispersed.

The coating the material for forming the organic layer in which the photochromic material is dispersed may be performed by using any one method of printing, depositing, and sputtering.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

Features will become apparent to those of ordinary skill in the art by describing in detail exemplary embodiments with reference to the attached drawings in which:

FIG. 1 is a cross-sectional view for describing an organic light emitting diode display according to an exemplary embodiment of the present disclosure.

FIG. 2 is a cross-sectional view for describing an encapsulation layer of the organic light emitting diode display according to the exemplary embodiment of the present disclosure.

FIGS. 3A to 3E are cross-sectional views for depicting stages in a manufacturing method of the organic light emitting diode display according to the exemplary embodiment of the present disclosure.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey examples of implementations to those skilled in the art. Accordingly, known processes, elements, and techniques are not described with respect to some of the embodiments. Exemplary embodiments to be described below and illustrated in the drawings may include various equivalences and modifications.

For reference, respective components and shapes thereof are schematically drawn or exaggeratedly drawn in the accompanying drawings for easy understanding. Like reference numerals designate like elements throughout the drawings.

Further, it will be understood that when a layer or an element is described as being “on” another layer or element, it may be directly disposed on another layer or element, or an intervening layer or element may also be present.

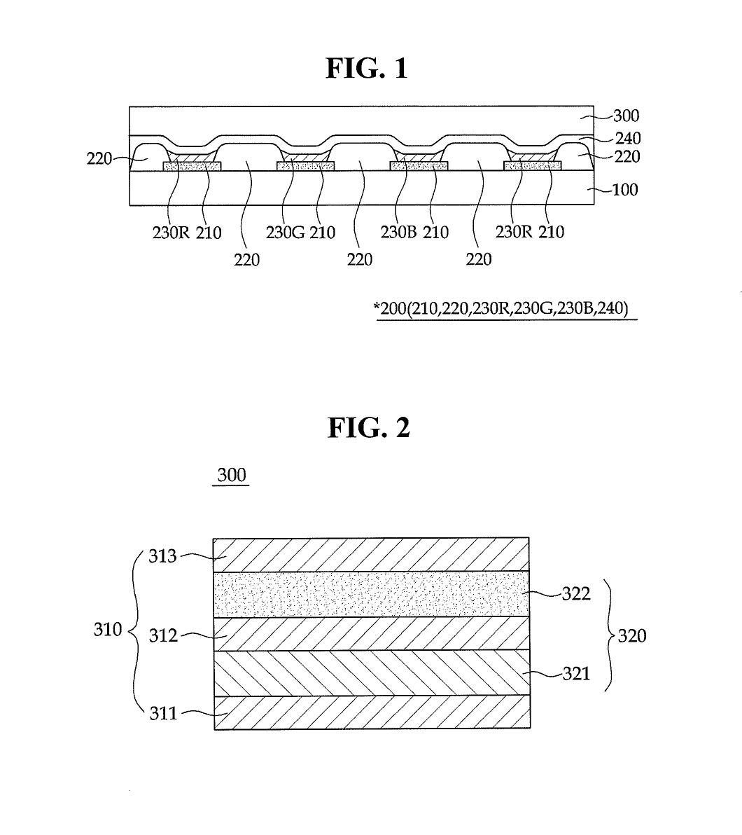

FIG. 1 is a cross-sectional view for describing an organic light emitting diode display according to an exemplary embodiment of the present disclosure.

Referring to FIG. 1, the organic light emitting diode display may include a substrate 100, an organic light emitting diode 200 disposed on the substrate 100, and an encapsulation layer 300 for sealing the organic light emitting diode 200.

The substrate 100 may be made of various materials such as a glass substrate, a quartz substrate, and a transparent resin substrate and may be formed by using a flexible material. The transparent resin substrate which may be used as the substrate 100 may include a polyimide resin, an acrylic resin, a polyacrylate resin, a polycarbonate resin, a polyether resin, a polyethylene terephthalate resin, a sulfonic acid resin, and the like.

In the case where the organic light emitting diode display is a rear emission type, the substrate 100 may be made of a light transmissive material, but in the case of a front emission type, the substrate may be made of the light transmissive material.

The organic light emitting diode 200 may include a plurality of first electrodes 210 disposed on the substrate 100, a pixel defining layer (PDL) 220 formed between the first electrodes 210 and overlapped with an end of the first electrode 210 to divide the first electrodes 210 by a pixel unit, an emission layer 230 disposed on the first electrode 210, and a second electrode 240 disposed on the emission layer 230.

In the case of a front emission type organic light emitting diode display, the first electrode 210 may be formed by containing at least one of gold (Au), platinum (Pt), nickel (Ni), tungsten (W), chromium (Cr), molybdenum (Mo), iron (Fe), cobalt (Co), copper (Cu), palladium (Pd), titanium (Ti), and a compound thereof. In addition, the second electrode 240 may be formed by containing at least one of indium tin oxide (ITO) and indium zinc oxide (IZO) which is transparent conductive oxide.

In the case of a rear emission type organic light emitting diode display, the first electrode 210 may be formed by containing at least one of indium tin oxide (ITO) and indium zinc oxide (IZO) which is transparent conductive oxide having high work function. In addition, the second electrode 240 may be formed of metal having low work function, that is, alkali metal such as lithium (Li) and cesium (Cs), and alkaline earth metal such as magnesium (Mg), calcium (Ca) and strontium (Sr), and their compounds.

According to other exemplary embodiments, the first electrode 210 and the second electrode 240 may be formed by containing various materials, e.g., by containing materials that are known in the art.

Although not illustrated in FIG. 1, a thin film transistor and an insulation layer protecting the thin film transistor may be further included between the substrate 100 and the first electrode 210. In this case, at least one thin film transistor may be formed for each pixel and electrically connected with the first electrode 210.

The emission layer 230 may include a red emission layer 230R, a green emission layer 230G, and a blue emission layer 230B. Further, a hole injection layer (HIL) and a hole transport layer (HTL) may be included between the first electrode 210 and the emission layer 230, and an electron transport layer (ETL) and an electron injection layer (EIL) may be included between the emission layer 230 and the second electrode 240.

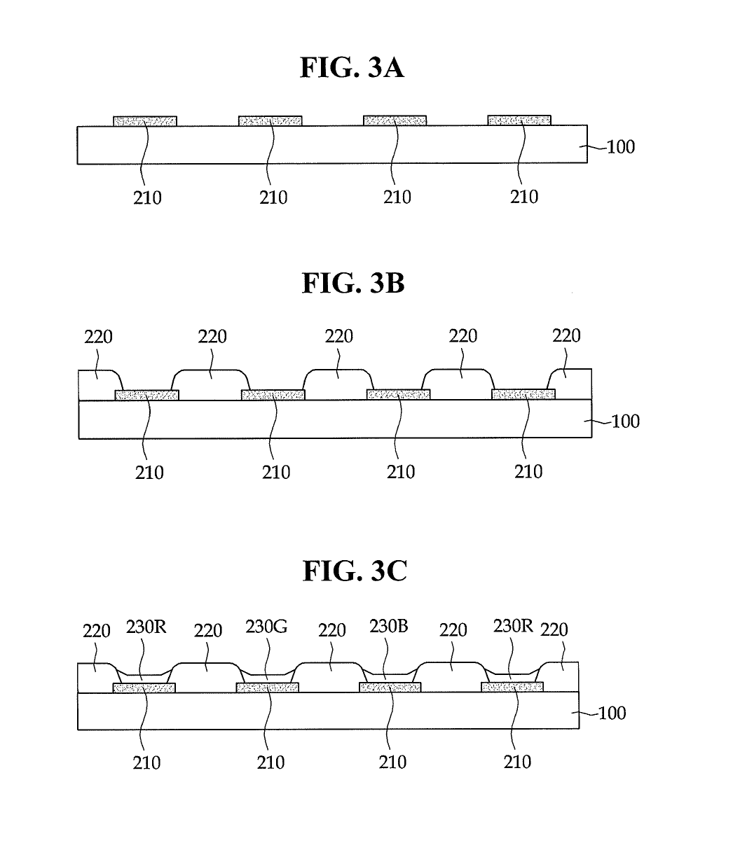

FIG. 2 is a cross-sectional view for describing an encapsulation layer 300 of the organic light emitting diode display according to the exemplary embodiment of the present disclosure.

The encapsulation layer 300 may be formed in a multilayered structure in which inorganic layers 310 and organic layers 320 are alternately laminated, and the encapsulation layer 300 is illustrated by a structure in which a first inorganic layer 311, a first organic layer 321, a second inorganic layer 312, a second organic layer 322, and a third inorganic layer 313 are laminated in FIG. 2. However, embodiments are not limited thereto, e.g., the encapsulation layer 300 may be formed by laminating additionally organic layers and inorganic layers.

Thin film materials, which are usable as the inorganic layers 310 and the organic layers 320, and a laminating method of the inorganic layers 310 and the organic layers 320 may be used without specific limitation, e.g., other thin film materials and laminating methods that are known in the art may be used.

The thin film material which is usable as the inorganic layer 310 may include at least one selected from a group consisting of silicon nitride, aluminum nitride, zirconium nitride, titanium nitride, hafnium nitride, tantalum nitride, silicon oxide, aluminum oxide, and titanium oxide.

The thin film material which is usable as the organic layer 320 may include at least one selected from perylene-3,4,9,10-tetracarboxylic dianhydride (PTCDA), biphenyl-tetracarboxylic acid dianhydride (BPDA), and pyromellitic dianhydride (PMDA).

In addition, other inorganic thin film materials or organic thin film materials, e.g., which are known in the art, may be used as a material of the inorganic layer 310 or the organic layer 320 according to the exemplary embodiment of the present disclosure.

The inorganic layer 310 and the organic layer 320 may formed by using any one of a spin coating process, a printing process, a sputtering process, a chemical vapor deposition (CVD) process, an atomic layer deposition (ALD) process, a plasma enhanced chemical vapor deposition (PECVD) process, a high density plasma-chemical vapor deposition (HDP-CVD) process, a vacuum deposition process, and the like according to a constituent material of the encapsulation layer 300.

The encapsulation layer 300 may be formed in a multilayered structure as illustrated in FIG. 2 and may contain a photochromic material in at least one layer.

The photochromic material is a material having a reversible characteristic which is when external light such as ultraviolet light is applied, colors of the photochromic material are changed, and when external light is blocked, the changed color returns to its original color again.

For example, in the case where the photochromic material is not exposed to external light such as ultraviolet light or solar light, the photochromic material is in a transparent state, but in the case where the photochromic material is exposed to the external light, the photochromic material absorbs the external light such as ultraviolet light or solar light and has colors such as violet, blue, yellow, and light gray.

Although the photochromic material absorbs the external light and the color of the photochromic material is changed, it may not be influenced to emit light generated in the emission layer of the organic light emitting diode display.

That is, a wavelength of light absorbed in the photochromic material and a wavelength of light emitted in the emission layer of the organic light emitting diode display may be different from each other.

The photochromic material may include at least one selected from a group a spiroxazine-based organic material, a spiropyran-based organic material, an azobenzo-based organic material, a naphthopyran-based organic material, a chromene-based organic material, an inorganic material such as AgCl, WO₃, TiO₂, and ZnS.

The photochromic material may be contained in at least one layer of the inorganic layers 310 or the organic layers 320 configuring the encapsulation layer 300 of the organic light emitting diode display.

It is preferred that the photochromic material may be contained in at least one layer of the organic layers 320.

In FIG. 2, the photochromic material is contained in a second organic layer 322 of the organic layers 320, but the photochromic material may be contained in a first organic layer 321 and may be contained in the inorganic layers 310.

The organic layer containing the photochromic material may be formed on an upper organic layer as illustrated in FIG. 2. When the organic layer containing the photochromic material is positioned on the encapsulation layer, external light which is incident to the organic light emitting diode display may be initially absorbed.

The content of the photochromic material is about 1% to about 20%. However, embodiments are not limited thereto, e.g., the content of the photochromic material may be about 3% to about 10% in the organic layer.

When the photochromic material is greater than about 1%, a photochromic effect may be realized, and when the photochromic material is less than about 20%, an encapsulation function of the organic layer containing the photochromic material may not be deteriorated.

The organic layer 320 containing the photochromic material may be formed by co-depositing a material for forming an organic layer such as organic monomers and the photochromic material.

Further, the organic layer 320 containing the photochromic material may be formed by a method of coating an emulsion-stated material made when the photochromic material is dispersed in the material for forming an organic layer such as organic monomers or spraying the emulsion-stated material through high-pressure nozzles.

The material for forming an organic layer in which the photochromic material is dispersed may be coated by using any one method of a spin coating process, a printing process, a sputtering process, a chemical vapor deposition (CVD) process, an atomic layer deposition (ALD) process, a plasma enhanced chemical vapor deposition (PECVD) process, a high density plasma-chemical vapor deposition (HDP-CVD) process, and a vacuum deposition process.

As such, the organic light emitting diode display containing the photochromic material may prevent reflection due to external light such as ultraviolet light without a polarizer or Polaroid film.

Further, the light emitted from the organic light emitting diode may be increased in an environment without external light as compared with the case of using the polarizer or Polaroid film.

Further, the organic layer 320 containing the photochromic material prevents the ultraviolet light from being reached into the organic light emitting diode display to protect the emission layer 230 of the organic light emitting diode display.

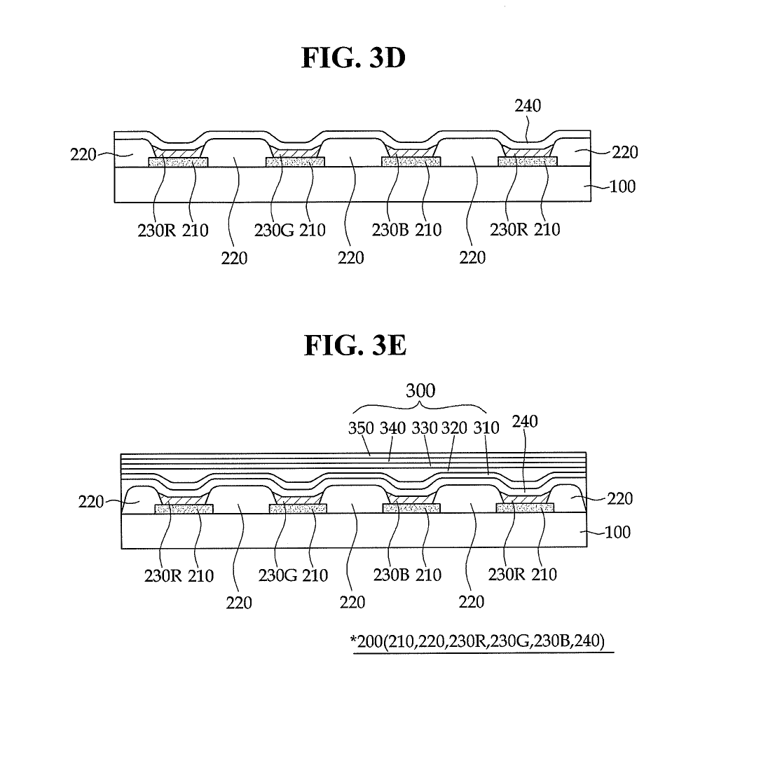

FIGS. 3A to 3E are cross-sectional views for describing a manufacturing method of the organic light emitting diode display according to the exemplary embodiment of the present disclosure.

The manufacturing method of the organic light emitting diode display according to the exemplary embodiment of the present disclosure may include (a) forming a plurality of first electrodes 210 on the substrate 100, (b) forming a pixel defining layer 220 between the plurality of first electrodes 210, (c) forming an emission layer on the first electrode, (d) forming a second electrode on the emission layer, and (e) forming an encapsulation layer on the second electrode.

The (e) forming of the encapsulation layer may further include forming an inorganic layer 310 and forming an organic layer 320.

The forming of the organic layer 320 may include forming an organic layer containing a photochromic material.

The forming of the organic layer containing the photochromic material may include co-depositing a material for forming the organic layer and the photochromic material at the same time.

The forming of the organic layer containing the photochromic material may include dispersing the photochromic material in the material for forming the organic layer and coating the material for forming the organic layer in which the photochromic material is dispersed.

The material for forming the organic layer in which the photochromic material is dispersed may be coated by using any one method of a spin coating process, a printing process, a sputtering process, a chemical vapor deposition (CVD) process, an atomic layer deposition (ALD) process, a plasma enhanced chemical vapor deposition (PECVD) process, a high density plasma-chemical vapor deposition (HDP-CVD) process, and a vacuum deposition process.

As described above, the organic light emitting diode display containing the photochromic material is only exemplified, and those skilled in the art can understand that the scope of the present disclosure may include various modification and equivalent embodiments therefrom.

By way of summation and review, an organic light emitting diode is an element that emits light when an electron supplied from a cathode is coupled with a hole supplied from an anode in an organic emission layer formed between the anode and the cathode. Since the organic light emitting diode may contain an organic material, the organic light emitting diode is vulnerable to moisture and oxygen. Accordingly, to protect the organic light emitting diode, the organic light emitting diode may be sealed by an encapsulation substrate made of glass, plastic, or the like.

Technology related to the encapsulation substrate may be difficult to apply to a thin and flexible organic light emitting diode display. Accordingly, to seal a thin and flexible organic light emitting diode display, a thin film encapsulation technology is proposed. The thin film encapsulation technology includes, e.g., sealing a display unit with a multilayer structure in which organic layers and inorganic layers are alternately laminated on the display unit.

However, when the organic light emitting diode display is viewed under an environment in which external light such as sunlight exists, visibility may be deteriorated due to light reflected onto the device. Accordingly, a polarizer or a Polaroid film may be applied onto the organic light emitting diode display. For example, reflection due to the external light may be reduced and/or prevented by attaching the polarizer or the Polaroid film onto the organic light emitting diode display, but the extraction efficiency of light generated from the organic emission layer may also be reduced due to the polarizer or the Polaroid film.

In contrast, embodiments relate to an organic light emitting diode display having an improved structure capable of minimizing and/or preventing deterioration of visibility due to external light and a manufacturing method thereof. Embodiments also relate to a light emitting diode display capable of minimizing and/or preventing visibility from being deteriorated due to external light and improving light extraction efficiency and a manufacturing method thereof.

Further, according to exemplary embodiments of the present disclosure, it is possible to protect an organic light emitting diode by shielding ultraviolet light in the organic light emitting display diode device.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An organic light emitting diode display, comprising:
a substrate;
a first electrode on the substrate;
an emission layer on the first electrode;
a second electrode on the emission layer; and
an encapsulation layer on the second electrode, the encapsulation layer having a multilayered structure and a photochromic material being within at least one layer of the multilayered structure.

2. The organic light emitting diode display as claimed in claim 1, wherein the photochromic material includes an ultraviolet sensitive material.

3. The organic light emitting diode display as claimed in claim 1, wherein the photochromic material includes at least one selected from the group of a spiroxazine-based organic material, a spiropyran-based organic material, an azobenzo-based organic material, a naphthopyran-based organic material, a chromene-based organic material, AgCl, WO₃, TiO₂, and ZnS.

4. The organic light emitting diode display as claimed in claim 1, wherein the multilayered structure of the encapsulation layer includes at least one organic layer and at least one inorganic layer.

5. The organic light emitting diode display as claimed in claim 4, wherein the at least one organic layer contains the photochromic material.

6. The organic light emitting diode display as claimed in claim 5, wherein an amount of the photochromic material is about 1% to about 20% in the organic layer containing the photochromic material.

7. A method of manufacturing an organic light emitting diode display, the method comprising:
forming a first electrode on a substrate;
forming an emission layer on the first electrode;
forming a second electrode on the emission layer; and
forming an encapsulation layer on the second electrode, forming the encapsulation layer including forming a layer containing a photochromic material.

8. The method as claimed in claim 7, wherein the photochromic material includes an ultraviolet sensitive material.

9. The method as claimed in claim 7, wherein the photochromic material includes at least one selected from the group of a spiroxazine-based organic material, a spiropyran-based organic material, an azobenzo-based organic material, a naphthopyran-based organic material, a chromene-based organic material, AgCl, WO₃, TiO₂, and ZnS.

10. The method as claimed in claim 7, wherein forming the encapsulation layer includes forming an organic layer and forming an inorganic layer.

11. The method as claimed in claim 10, wherein forming the encapsulation layer includes alternately forming the organic layer and the inorganic layer.

12. The method as claimed in claim 10, wherein the organic layer and the inorganic layer are each independently formed by any one of a spin coating process, a printing process, a sputtering process, a chemical vapor deposition (CVD) process, an atomic layer deposition (ALD) process, a plasma enhanced chemical vapor deposition (PECVD) process, a high density plasma-chemical vapor deposition (HDP-CVD) process, and a vacuum deposition process.

13. The method as claimed in claim 10, wherein forming the organic layer includes forming an organic layer including the photochromic material.

14. The method as claimed in claim 13, wherein, when forming the organic layer including the photochromic material, a material for forming the organic layer and the photochromic material are co-deposited.

15. The method as claimed in claim 13, wherein forming the organic layer including the photochromic material includes:
dispersing the photochromic material into a material for forming the organic layer, and
coating the material for forming the organic layer in which the photochromic material is dispersed.

16. The method as claimed in claim 15, wherein coating the material for forming the organic layer in which the photochromic material is dispersed includes any one of a spin coating process, a printing process, a sputtering process, a chemical vapor deposition (CVD) process, an atomic layer deposition (ALD) process, a plasma enhanced chemical vapor deposition (PECVD) process, a high density plasma-chemical vapor deposition (HDP-CVD) process, and a vacuum deposition process.
